(19) United States
(12) Patent Application Publication
(10) Pub. No.: US 2025/0011969 A1
(43) Pub. Date: Jan. 9, 2025

(54) GROUP 13 NITRIDE SINGLE CRYSTAL SUBSTRATE

(71) Applicant: NGK INSULATORS, LTD., Nagoya-shi (JP)

(72) Inventors: Katsuhiro IMAI, Nagoya-shi (JP); Yoshinori ISODA, Nagoya-shi (JP); Kenta IMAZU, Nagoya-shi (JP)

(21) Appl. No.: 18/897,279

(22) Filed: Sep. 26, 2024

Related U.S. Application Data
(63) Continuation of application No. PCT/JP2023/002045, filed on Jan. 24, 2023.

(30) Foreign Application Priority Data
Mar. 29, 2022 (JP) 2022-053676

(51) Int. Cl. C30B 29/40; C30B 9/12

(52) U.S. Cl. CPC C30B 29/406; C30B 9/12

(57) ABSTRACT

The object is to increase the specific resistance of and to suppress warping and cracks in a group 13 nitride single crystal substrate. The group 13 nitride single crystal substrate is composed of a group 13 nitride single crystal and has a first main face and a second main face. The group 13 nitride single crystal contain manganese and zinc as dopants.

### CROSS-REFERENCE TO RELATED APPLICATIONS

This application is a continuation application of PCT/JP 2023/002045, filed Jan. 24, 2023, which claims priority to Japanese Application No. JP 2022-053676 filed on Mar. 29, 2022, the entire contents all of which are incorporated hereby by reference.

### TECHNICAL FIELD

The present invention is related to a group 13 nitride single crystal substrate.

### BACKGROUND ARTS

A gallium nitride free-standing substrate has been applied, for producing various kinds of devices such as ultra-high luminance LED, high output power LD, high efficiency power IC or the like including a gallium nitride-based compound semiconductor. In the field of power devices such as power IC, as a larger electric power is supplied, the size of the device is made preferably larger. This is because the fracture of the device is suppressed by enlarging the area of the device and by lowering the current density. Thus, the development of a gallium nitride free-standing substrate having a large size such as 4 inches or 6 inches has been activated. As methods for producing the gallium nitride free-standing substrate, HVPE method, ammonothermal method, flux method and the like are known.

Recently, as the digitalization of social infrastructure is progressed, the demand for high-speed transmission of communication data of a large capacity is increased so that the frequency is increased in wireless communication. As gallium nitride having material property of a large electron mobility is suitable for a high electron mobility transistor (HEMT) applied in a power amplifier or the like in a wireless communication base, an HEMT device is more widely applied having SiC structure on GaN in which gallium nitride as a functional layer is laminated on a high-resistance silicon carbide substrate. As the functional layer is composed of gallium nitride, the development of the high-resistance gallium nitride free-standing substrate is demanded for producing HEMT devices having higher performance. If the high-resistance gallium nitride free-standing substrate is provided, it becomes possible to form the gallium nitride functional layer with reduced defects. It can be thereby expected to realize the HEMT device having higher performance. Here, the higher performance means the device having high output power of communication wave and high energy conversion efficiency.

A high-resistance gallium nitride substrate with doped zinc or high resistance gallium nitride substrate with doped iron has been reported until now (Patent documents 1, 2 and 3).

### PATENT DOCUMENTS

(Patent document 1) Japanese patent publication No. 2011-020896A
(Patent document 2) Japanese patent publication No. 2019-001673A
(Patent document 3) Japanese patent publication No. 2007-534580A

### SUMMARY OF THE INVENTION

However, for example, although the high-resistance gallium nitride substrate of 4 inches or larger is required for producing the HEMT device applied in a power amplifier or the like for use in wireless communication stations, the substrate is difficult to produce so that the practical utilization has not been made.

An object of the present invention is to improve the specific resistance of and to suppress the warping and cracks in a group 13 nitride single crystal substrate.

The present invention provides a group 13 nitride single crystal substrate comprising a group 13 nitride single crystal and having a first main face and a second main face, wherein said group 13 nitride single crystal comprises manganese and zinc as dopants.

Further, the present invention provides a method of producing the group 13 nitride single crystal substrate as described above, the method comprising immersing a seed substrate in a flux containing manganese and zinc and growing said group 13 nitride single crystal on said seed substrate by a flux method to provide said group 13 nitride single crystal substrate.

According to the present invention, it is possible to improve the specific resistance of and to control the warping and cracks of a group 13 nitride single crystal substrate.

Here, in the case that only zinc is added to a group 13 nitride single crystal substrate, although the specific resistance of the group 13 nitride single crystal substrate is increased, it is found that the group 13 nitride single crystal tends to be warped in concave shape viewed on the side of the growth surface and that cracks tends to be generated. Further, for example, for obtaining a high resistance value required for producing an HEMT device, it is necessary to increase the doping amount of zinc. As the doping amount of zinc is increased, the warping and cracks described above may be more easily generated.

Further, the present inventors studied to dope manganese into a group 13 nitride single crystal. In this case, the resistance value of the group 13 nitride single crystal is considerably increased by adding a minute amount of manganese. On the other hand, it is found that the grown group 13 nitride single crystal tends to be easily warped in convex shape with respect to the growth surface and that cracks are easily generated. It is proved that the resistance value is not sufficiently high over the whole of the group 13 nitride single crystal in the case that the added amount of manganese is further reduced for suppressing the warping and cracks.

As such, it is found that both of zinc and manganese have the effect of increasing the resistance of the group 13 nitride single crystal substrate and, at the same time, that the effects applied on the heteroepitaxial growth of the group 13 nitride single crystal on the underlying substrate are contrary to each other. The present inventors have noted such effects and added zinc and manganese at the same time so that it is successfully provided the group 13 nitride single crystal substrate having a large size, small warping, suppressed the cracks and high resistance.

### BRIEF DESCRIPTION OF THE DRAWINGS

FIG. 1A is a schematic view showing an epitaxial substrate 1 for a semiconductor device according to an embodiment, and

FIG. 1B is a schematic view showing a composite substrate 8 for depositing an epitaxial growth layer.

### MODES FOR CARRYING OUT THE INVENTION

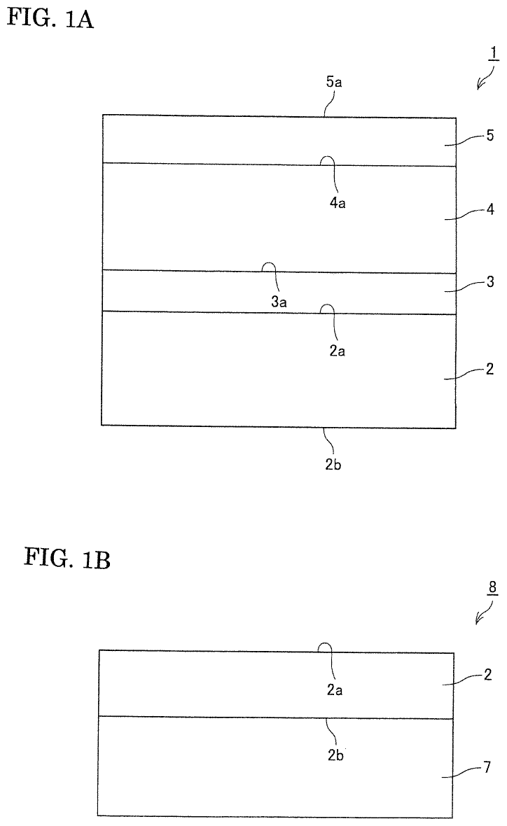

FIG. 1A is a schematic view showing an epitaxial substrate 1 for a semiconductor device according to an embodiment.

A group 13 nitride single crystal substrate 2 of the present invention has a first main face 2a and a second main face 2b. The first main face 2a of the group 13 nitride single crystal substrate 2 is selected as a deposition surface, and an epitaxial growth layer is deposited on the first main face 2a. Specifically, according to the present example, a buffer layer 3 is formed on the first main face 2a of the group 13 nitride single crystal substrate 2, a channel layer 4 is formed on a main face 3a of the buffer layer 3, and a barrier layer 5 is formed on a main face 4a of the channel layer 4. Predetermined electrodes may be provided on the main face 5a of the barrier layer 5.

The group 13 nitride single crystal substrate 2 is composed of group 13 nitride single crystal and has a first main face 2a and a second main face 2b.

The group 13 element is a group 13 element defined in IUPAC, and may particularly preferably be gallium, aluminum and/or indium. Further, the group 13 nitride single crystal may preferably be a group 13 nitride single crystal selected from gallium nitride, aluminum nitride, indium nitride or the mixed crystals thereof. More specifically, GaN, AlN, InN, GaxAl1−xN (1>x>0), GaxIn1−xN (1>x>0), AlxIn1−xN (1>x>0) and GaxAlyInzN (1>x>0.1>y>0, x+y+z=1) are listed.

According to a preferred embodiment, the ratio (concentration of manganese/concentration of zinc) of the concentration of manganese with respect to the concentration of zinc is made 0.5 or higher and 30 or lower. By making the ratio 0.5 or higher, it is possible to suppress the warping of the concave shape of the group 13 nitride single crystal substrate and cracks due to the warping of the concave shape and to further increase the specific resistance. Further, by making the ratio 30 or lower, it is possible to suppress the warping of the convex shape of the group 13 nitride single crystal substrate and to suppress cracks due to the warping of the convex shape. On such viewpoint, the ratio (concentration of manganese/concentration of zinc) of the concentration of manganese with respect to the concentration of zinc may preferably be made 3.0 or higher and more preferably be made 5.0 or higher. Further, the ratio (concentration of manganese/concentration of zinc) of the concentration of manganese with respect to the concentration of zinc may preferably be made 25 or lower and more preferably be made 20 or lower.

On the viewpoint of the present invention, the concentration of manganese of the group 13 nitride single crystal may preferably be 1×10¹⁸ atoms/cm³ to 1×10¹⁹ atoms/cm³ and more preferably be 2×10¹⁸ atoms/cm³ to 5×10¹⁸ atoms/cm³. Further, on the viewpoint of the present invention, the zinc concentration of the group 13 nitride single crystal may preferably be 1×10¹⁷ atoms/cm³ to 3×10¹⁸ atoms/cm³ and more preferably be 2×10¹⁷ atoms/cm³ to 1×10¹⁸ atoms/cm³. Further, the concentration of manganese and concentration of zinc of the group 13 nitride single crystal are to be measured by SIMS (Secondary ion mass spectroscopy).

Further, the group 13 nitride single crystal may contain an element other than zinc and manganese. As the element, for example, hydrogen (H), oxygen (O), silicon (Si), iron (Fe), chromium (Cr) and the like are listed.

The definition of the single crystal will be described. Although it is included a single crystal, described in textbooks, in which atoms are regularly arranged over the whole of the crystal, it is not meant to be limited to only such mode and it is meant to include single crystals generally supplied in the industry. That is, the crystal may contain some degree of defects, or deformation may be inherent, or an impurity may be incorporated.

Further, the group 13 nitride single crystal substrate may be a free-standing substrate. The term “free-standing substrate” means a substrate that are not deformed or broken under its own weight during handling and can be handled as a solid. The free-standing substrate of the present invention can be used as a substrate for various types of semiconductor devices such as light emitting devices.

According to a preferred embodiment, the thickness of the free-standing substrate after the polishing may preferably be 300 μm or larger and preferably be 1000 μm or smaller.

Although the size of the free-standing substrate is not particularly limited, the size is 4 inches or larger, may be 6 inches or larger and may be 8 inches or larger.

Further, as shown in FIG. 1B, an underlying substrate 7 composed of a material, whose thermal conductivity is higher than that of the group 13 nitride single crystal, is directly bonded to the side of the second main face 2b of the group 13 nitride single crystal substrate 2, so that a composite substrate 8 for depositing an epitaxial growth layer is provided. The material of such underlying substrate may preferably be SiC, AlN or diamond. Further, the thermal conductivity of the underlying substrate may preferably be 200 W/m·K or higher and more preferably be 500 W/m·K or higher.

It is possible to provide an HEMT device capable of operating at a high output power, by applying the group 13 nitride single crystal substrate of the present invention as a template. It is possible to provide a power amplifier of a high output power and high efficiency at a high frequency required for a base station for next-generation wireless communication, by applying such HEMT device.

According to a preferred embodiment, the group 13 nitride single crystal substrate has a specific resistance at room temperature of 1×10⁶ Ω·cm or higher. That is, the group 13 nitride single crystal substrate is of semi-insulating. On such viewpoint, the specific resistance at room temperature of the group 13 nitride single crystal substrate may preferably be 1×10⁷ Ω·cm or higher and more preferably be 1×10⁹ Ω·cm or higher. Further, the specific resistance at room temperature of the group 13 nitride single crystal substrate is 1×10¹³ Ω·cm or lower in many cases.

### (Production of Group 13 Nitride Single Crystal Substrate)

The method of producing the group 13 nitride single crystal substrate may be a vapor phase method such as Metal Organic Chemical Vapor Deposition (MOCVD) method, hydride vapor phase epitaxy (HVPE) method, pulse-excited deposition (PXD) method, MBE method, sublimation method or the like, or a liquid phase method such as ammonothermal method, flux method or the like. More preferably, the group 13 nitride single crystal is that produced by flux method.

In the case of flux method, it is preferred to immerse a seed substrate in flux containing manganese and zinc and to grow the group 13 nitride single crystal on the seed substrate by flux method to obtain the group 13 nitride single crystal substrate. More preferably, it is preferred to provide a seed crystal film on a surface of a supporting substrate such as sapphire or group 13 nitride single crystal to provide a seed substrate and to grow the group 13 nitride single crystal on the seed crystal film by flux method.

Although it is preferred that the material of the supporting substrate and the material of the group 13 nitride single crystal substrate of the present invention are of different kinds, the materials may be of the same kind.

Further, as one of the methods of producing the group 13 nitride single crystal substrate, there is the method of heteroepitaxial growth on the underlying substrate composed of the different kind of material such as sapphire to produce the group 13 nitride single crystal and of processing it to obtain the group 13 nitride single crystal substrate.

However, according to such method, the warping may easily occur and cracks may be generated in the group 13 nitride single crystal substrate, due to the mismatch of the lattice constants and the difference of the thermal expansion coefficients of the group 13 nitride single crystal and sapphire. Particularly, as the size of the group 13 nitride single crystal substrate is larger, the difference with the underlying substrate and is accumulated to provide considerable influence, so that the absolute value of the warping is lager and crack are more frequently generated.

AlxGa1−xN (0≤x≤1) or InxGa1−xN (0≤x≤1) may be listed as preferred examples as the material of the seed crystal film, and gallium nitride is particularly preferred.

The method of forming the seed crystal film may preferably be a vapor phase deposition method, and Metal Organic Chemical Vapor Deposition (MOCVD) method, hydride vapor phase deposition (HVPE) method, pulse-excited deposition (PXD) method, MBE method and sublimation method are listed. Metal Organic Chemical Vapor Deposition method is most preferred. Further, the growth temperature may preferably 950 to 1200° C.

In the case that the group 13 nitride single crystal is grown by flux method, the kind of the flux is not particularly limited, as far as the single crystal can be generated. According to a preferred embodiment, the flux contains at least one of an alkali metal and alkaline earth metal and the flux containing sodium metal is particularly preferred.

A raw material substance of a metal is mixed with the flux and applied. The raw material substrate of a metal may be a single metal, alloy or metal compound, and the single metal is preferred on the viewpoint of handling.

The growth temperature and holding time for the growth of the group 13 nitride single crystal by flux method are not particularly limited and may be appropriately changed depending on the composition of the flux. For example, in the case that gallium nitride crystal is grown by applying the flux containing sodium or lithium, the growth temperature may preferably be 800 to 950° C. and more preferably be 850 to 900° C.

According to flux method, the group 13 nitride single crystal is grown under atmosphere containing a gas including nitrogen atom. The gas may preferably be nitrogen gas and may be ammonia. Although the pressure of the atmosphere is not particularly limited and may preferably be 10 atoms or higher and more preferably be 30 atoms or higher on the viewpoint of preventing the evaporation of the flux. However, as the pressure is higher, the scale of the system becomes larger. Thus, the total pressure of the atmosphere may preferably be 2000 atoms or lower and more preferably be 500 atoms or lower. Although the gas other than the gas including nitrogen atom in the atmosphere is not limited, an inert gas is preferred, and argon, helium or neon is particularly preferred.

According to a particularly preferred embodiment, a seed crystal film composed of gallium nitride is grown on a sapphire substrate by MOCVD method to obtain a seed substrate. The seed substrate is mounted in a crucible and 10 to 50 mol % of Ga metal, 50 to 90 mass parts of Na metal, 0.0001 to 1 mol % of Mn metal and 0.0001 to 1 mol % of Zn metal are then filled in the crucible. The added amount of the Mn metal and added amount of Zn metal are appropriately adjusted in the ranges described above to control the respective concentrations of the group 13 nitride single crystal. The crucible is contained in a heating furnace, the temperature in the furnace is made 800° C. to 950° C., the pressure in the furnace is made 3 MPa to 5 MPa, the heating is performed for 20 hours to 400 hours and the temperature is then cooled to room temperature. After the termination of the cooling, the crucible is drawn out of the furnace.

The thus obtained gallium nitride single crystal is polished with diamond abrasives to flatten the surface. The gallium nitride single crystal is thereby formed on the seed crystal film.

### (Formation of Epitaxial Growth Layer)

As the epitaxial growth layer grown on the group 13 nitride single crystal substrate, gallium nitride, aluminum nitride, indium nitride or the mixed crystals thereof are exemplified. Specifically, GaN, AlN, InN, GaxAl1−xN (1>x>0), GaxIn1−xN (1>x>0), AlxIn1−xN (1>x>0) or GaxAlyInzN (1>x>0, 1>>>0, x+y+z=1) are listed. Further, as a functional layer provided on the group 13 nitride single crystal substrate, a rectifying element layer, switching element layer or the like may be listed in addition to a light-emitting layer.

According to a preferred embodiment, for example as shown in FIG. 1A, a buffer layer 3, channel layer 4 and barrier layer 5 are formed on a first main face 2a of a group 13 nitride single crystal substrate 2.

The formation of the buffer layer 3, channel layer 4 and barrier layer 5 can be performed by, for example, metal organic chemical vapor deposition (MOCVD) method. According the formation of the layers with MOCVD method, metal organic raw material gases (TMG (trimethyl gallium), TMA (trimethyl aluminum), TMI (trimethyl indium) or the like) depending on the target composition, ammonia gas, hydrogen gas and nitrogen gas are supplied into a reactor of an MOCVD furnace, and the group 13 nitride single crystals are subsequently generated by the vapor phase reaction of the metal organic raw material gases corresponding with the respective layers and ammonia gas while the group 13 nitride single crystal substrate mounted in the reactor is heated at a predetermined temperature.

### (Measurement of Cross-Sectional Shape and Warping)

The cross-sectional shape and warping of the group 13 nitride single crystal substrate are to be measured as follows. “FlatMaster 200” produced by Tropel Corporation is applied, the group 13 nitride single crystal substrate is left to stand on a sample stage with the group 13 element polarity surface facing upwardly, and the shape of the substrate was measured by “Medium range” to provide smooth curved shape. It is assigned concave shape in the case that the outer peripheral part is higher with respect to the center of the group 13 nitride single crystal substrate (wafer), and it is assigned convex shape in the case that the outer peripheral part is lower with respect to the center of the group 13 nitride single crystal substrate (wafer). Further, the value of the warping is defined as a total of a distance between the minimum square plane of the curved surface described above and the highest point on the surface of the wafer and a distance between the minimum square plane described above and the lowest point on the surface of the wafer.

Further, in the case that the diameter of the group 13 nitride single crystal substrate is 4 inches or larger, the absolute value of the warping is measured and calculated in a range of a diameter of 4 inches with respect to the center of the substrate. Further, in the case that the diameter of the group 13 nitride single crystal is smaller than 4 inches, the absolute value of the warping is measured and calculated in a range of a diameter of 2 inches with respect to the center of the substrate.

Further, in the case that the diameter of the group 13 nitride single crystal substrate is 4 inches or larger, the absolute value of the warping may preferably be 50 μm or smaller, more preferably be 25 μm or smaller and most preferably be 15 μm or smaller. In the case that the diameter of the group 13 nitride single crystal substrate is 2 inches, the absolute value of the warping may preferably be 20 μm or smaller.

### Examples

As described below, the respective gallium nitride single crystal substrates of the inventive examples 1 to 4 and comparative examples 1 and 2 shown in table 1 were produced and the manganese concentration, zinc concentration, cross-sectional shape, warping, presence and absence of cracks and specific resistance of each was measured. The results were shown in table 1.

### (Production of Gallium Nitride Single Crystal Substrate)

### (Production of Seed Substrate)

A seed crystal film composed of gallium nitride and having a thickness of 2 μm was deposited on a surface of c-plane sapphire substrate (underlying substrate) having a diameter of 4 inches by MOCVD method, to provide a seed substrate.

### (Growth of Gallium Nitride Single Crystal by Na Flux Method)

Gallium nitride single crystal was grown by Na flux method on the seed substrate described above. Specifically, 50 g of Ga metal, 100 g of Na metal, Mn metal and Zn metal were filled in an alumina crucible, respectively, and the crucible was closed with an alumina lid. The amounts of Mn metal and Zn metal are appropriately adjusted in a range of 1 mg to 10 g. The crucible was contained in a heating furnace, the temperature in the furnace was made 850° C., the pressure in the furnace was made 4.0 MPa, and the heating was performed over 100 hours, followed by cooling to room temperature. After the termination of cooling, the alumina crucible was drawn out of the furnace. It was thus observed that brown gallium nitride single crystal was deposited on the surface of the seed substrate in a thickness of about 1000 μm.

### (Production of Free-Standing Substrate)

The thus obtained gallium nitride single crystal was polished by diamond abrasives to flatten the surface so that the total thickness of the gallium nitride single crystal formed on the underlying substrate was made 700 μm.

The seed substrate was separated from the gallium nitride single crystal by laser lift-off method to obtain a gallium nitride single crystal substrate.

The first main face and second main face of the gallium nitride single crystal substrate were polished to obtain a free-standing substrate composed of gallium nitride single crystal and having a thickness of 400 μm.

### (Measurement of Concentrations of Manganese and Zinc)

The manganese concentrations and zinc concentrations of the thus obtained respective gallium nitride single crystal substrates were measured by SIMS (Secondary ion mass spectroscopy method). Specific measurement conditions are as follows.
Measuring system: “CAMECA IMA-6f”, Primary ion specie: Cs+, acceleration voltage: 15 kV, detection area: 30 μmΦ

### (Measurement of Cross-Sectional Shape and Warping)

The cross-sectional shape and warping of the gallium nitride single crystal substrate of each example were measured as described above.

### (Measurement of Specific Resistance)

The specific resistance of the gallium nitride single crystal substrate of each example was measured by electrical resistance method (“COREMA-WT” manufactured by SEMIMAP corporation).

### (Observation of Cracks)

The thus obtained underlying substrates and gallium nitride single crystal substrates of the respective examples were observed by eyes to confirm the presence or absence of cracks.

TABLE 1

| | | Com. | Inv. | Inv. | Inv. | Inv. | Com. |
|---|---|---|---|---|---|---|---|
| | | Ex. 1 | Ex. 1 | Ex. 2 | Ex. 3 | Ex. 4 | Ex. 2 |
| Concentration | Mn | Under | 1.8 | 3.8 | 1.9 | 4.1 | 4 |
| ×10¹⁸/cm³ | | Detection | | | | | |
| | | limit | | | | | |
| | Zn | 3.9 | 2.2 | 0.96 | 0.21 | 0.18 | Under |
| | | | | | | | Detection |
| | | | | | | | limit |
| Ratio of | Mn/Zn | — | 0.82 | 3.96 | 9.05 | 22.78 | — |
| concentrations | | | | | | | |
| Cross-sectional | | Concave | slightly | Slightly | flat | Slightly | Convex |
| shape | | shape | Concave | Concave | | convex | shape |
| | | | shape | shape | | shape | |
| Warping (μm) | | −80 | −30 | −10 | 0 | +20 | +60 |
| Specific | | 10⁵ | 10⁶ | 10⁷ | 10¹⁰ | 10¹¹ | 10¹¹ |
| resistance | | | | | | | |
| (Ω · cm) | | | | | | | |
| Crack | | Present | Absent | Absent | Absent | Absent | Present |

As shown in table 1, according to the gallium nitride single crystal substrate of the present invention, it is proved that the absolute value of the warping is low, the cracks are not observed and the specific resistance is as high as 10⁶ Ω·cm or higher.

On the contrary, according to the comparative example 1, although 3.9×10¹⁸/cm³ of zinc was contained in the gallium nitride single crystal, manganese was not contained therein. As a result, the specific resistance is 105 Ω·cm, the gallium nitride single crystal substrate was warped in concave shape with respect to the growth surface, the warping reached minus 80 μm and cracks were observed. The warping is further increased, in the case that the concentration of zinc is further increased to increase the specific resistance.

On the other hand, according to the comparative example 2, 4×10¹⁸/cm³ of manganese may be contained in the gallium nitride single crystal and zinc is not contained therein. As a result, although the specific resistance is as high as 10¹¹ Ω·cm, the gallium nitride single crystal substrate is warped in convex shape with respect to the growth surface, the warping reached +60 μm, and the cracks were observed.

1. A group 13 nitride single crystal substrate comprising a group 13 nitride single crystal and having a first main face and a second main face,
wherein said group 13 nitride single crystal comprises manganese and zinc as dopants.

2. The group 13 nitride single crystal substrate of claim 1, wherein a ratio of a concentration of manganese with respect to a concentration of zinc (the concentration of manganese/the concentration of zinc) is 0.5 or higher and 30 or lower.

3. The group 13 nitride single crystal substrate of claim 1, wherein said group 13 nitride single crystal substrate has a specific resistance at room temperature of 1×10⁶ Ω·cm or higher.

4. The group 13 nitride single crystal substrate of claim 1, wherein said group 13 nitride single crystal substrate has an absolute value of warping of 50 μm or smaller.

5. The group 13 nitride single crystal substrate of claim 1, wherein said group 13 nitride single crystal is produced by a flux method.

6. A method of producing the group 13 nitride single crystal substrate of claim 1, said method comprising:
immersing a seed substrate into a flux containing manganese and zinc and growing said group 13 nitride single crystal on said seed substrate by a flux method to provide said group 13 nitride single crystal substrate.
